(19) United States
(12) Patent Application Publication
(10) Pub. No.: US 2024/0404863 A1
(43) Pub. Date: Dec. 5, 2024

(54) METHOD FOR FABRICATING SEMICONDUCTOR DEVICE

(71) Applicant: Samsung Electronics Co., Ltd., Suwon-si (KR)

(72) Inventors: Kwang Yong YU, Suwon-si (KR); Woo Jeong SHIN, Suwon-si (KR); Il Hwan KIM, Suwon-si (KR); Chang Min PARK, Suwon-si (KR); Hee Sun JUN, Suwon-si (KR)

(73) Assignee: Samsung Electronics Co., Ltd., Suwon-si (KR)

(21) Appl. No.: 18/407,872

(22) Filed: Jan. 9, 2024

(30) Foreign Application Priority Data
Jun. 2, 2023 (KR) 10-2023-0071461

(51) Int. Cl. H01L 21/683; H01L 21/56; H01L 21/768; H01L 23/522

(52) U.S. Cl. CPC H01L 21/6835; H01L 21/56; H01L 21/76802; H01L 23/5226; H01L 2221/68359

(57) ABSTRACT

A method for fabricating a semiconductor device may include forming a first substrate including a first surface and a second surface, which may be opposite each other, forming a first semiconductor element on the first surface, adhering the first substrate onto a second substrate so that an upper surface of the second substrate faces the first surface of the first substrate, removing an edge region of the first substrate, forming a passivation layer surrounding first sides of the first substrate, and forming a second semiconductor element on the second surface of the first substrate. The passivation layer may not be formed on the second surface of the first substrate.

### CROSS-REFERENCE TO RELATED APPLICATION

This application claims priority from Korean Patent Application No. 10-2023-0071461 filed on Jun. 2, 2023, in the Korean Intellectual Property Office and all the benefits accruing therefrom under 35 U.S.C. 119, the contents of which in its entirety are herein incorporated by reference.

### BACKGROUND

### Technical Field

The present disclosure relates to a method for fabricating a semiconductor device.

### Description of the Related Art

Many wafers may include bevel edges generated by a wafer thinning process. When mechanical stress and thermal stress, which are generated by a fabricating process of a semiconductor device, are applied to a wafer, a bevel may add uneven stress to an edge of the wafer. As a result, wafer cracks and delamination may occur. Therefore, it may be necessary to remove the bevel edge through a trimming process of the edge of the wafer.

Meanwhile, as a thickness of the wafer is increased, a step difference occurs in an edge region of the wafer after the edge of the wafer is trimmed. When a pattern is formed on the wafer, the pattern is not stably formed in the edge region with a step difference of the wafer.

### BRIEF SUMMARY

The present disclosure relates to a method for fabricating a semiconductor device, in which product reliability is improved.

According to an embodiment of inventive concepts, a method for fabricating a semiconductor device may include forming a first substrate including a first surface and a second surface, which may be opposite each other; forming a first semiconductor element on the first surface; adhering the first substrate onto a second substrate so that an upper surface of the second substrate faces the first surface of the first substrate; removing an edge region of the first substrate; forming a passivation layer surrounding first sides of the first substrate; and forming a second semiconductor clement on the second surface of the first substrate. The passivation layer may not be formed on the second surface of the first substrate.

According to an embodiment of inventive concepts, a method for fabricating a semiconductor device may include adhering a second substrate on a first substrate, the second substrate including a second surface facing a first surface of the first substrate; forming a passivation layer surrounding sides of the second substrate on the first substrate; forming a first semiconductor element on a third surface of the second substrate, the third surface of the first substrate being opposite the second surface of the second substrate; and removing the passivation layer. The first substrate may have a first width. The second substrate may have a second width. The second width may be smaller than the first width. The passivation layer may not be formed on the third surface of the second substrate.

According to an embodiment of inventive concepts, a method for fabricating a semiconductor device may include forming a first substrate including a first surface and a second surface, which may be opposite each other; forming a first semiconductor element on the first surface; adhering the first substrate onto an upper surface of a second substrate so that the upper surface of the second substrate faces the first surface; forming first sides of the first substrate by removing an edge region of the first substrate; forming a mask layer on the second surface of the first substrate; forming a passivation layer surrounding the first sides of the first substrate and sides of the mask layer; patterning the mask layer to provide a patterned mask layer; removing the passivation layer; and forming a second semiconductor element electrically connected to the first semiconductor element on the second surface of the first substrate. The forming the second semiconductor element may include using the patterned mask layer as a patterning mask. A first width between the first sides of the first substrate may be smaller than a second width between second sides of the second substrate. The passivation layer may not be formed on the second surface of the first substrate. The passivation layer may include a photoresist material.

Aspects of the present disclosure are not limited to those mentioned above and additional aspects of the present disclosure, which are not mentioned herein, will be clearly understood by those skilled in the art from the following description of the present disclosure.

### BRIEF DESCRIPTION OF THE DRAWINGS

The above and other aspects and features of the present disclosure will become more apparent by describing in detail example embodiments thereof with reference to the attached drawings, in which:

FIGS. 1 to 16 are views illustrating intermediate operations to describe a method for fabricating a semiconductor device according to some embodiments of the present disclosure.

FIG. 17 is a view illustrating intermediate operations to describe a method for fabricating a semiconductor device according to some other embodiments of the present disclosure.

FIG. 18 is a view illustrating intermediate operations to describe a method for fabricating a semiconductor device according to some other embodiments of the present disclosure.

FIG. 19 is a view illustrating intermediate operations to describe a method for fabricating a semiconductor device according to some other embodiments of the present disclosure.

FIG. 20 is a layout view illustrating a semiconductor device according to some embodiments of the present disclosure.

FIG. 21 is a cross-sectional view taken along line A-A of FIG. 20.

FIG. 22 is a cross-sectional view taken along line B-B of FIG. 20.

FIG. 23 is a cross-sectional view taken along line C-C of FIG. 20.

FIG. 24 is a cross-sectional view taken along line D-D of FIG. 20.

### DETAILED DESCRIPTION OF THE DISCLOSURE

Hereinafter, the embodiments according to technical spirits of the present disclosure will be described with the accompanying drawings.

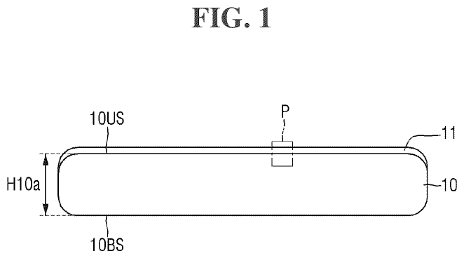

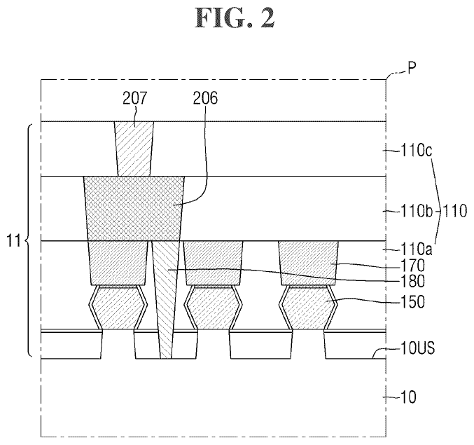

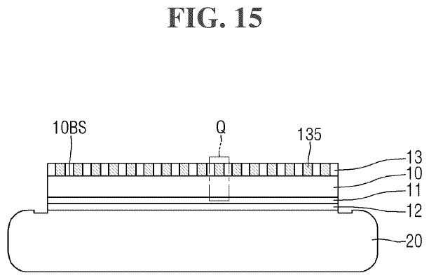

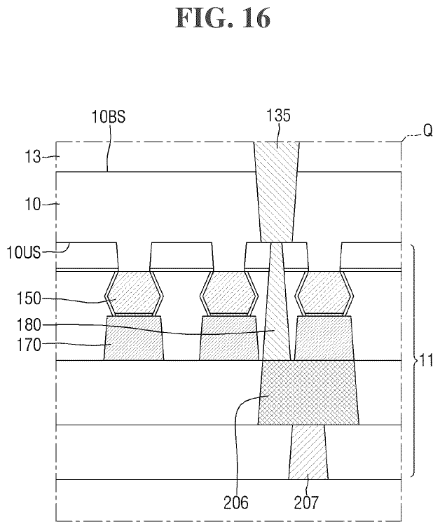

FIGS. 1 to 16 are views illustrating intermediate operations to describe a method for fabricating a semiconductor device according to some embodiments of the present disclosure. For reference, FIG. 2 is an enlarged view illustrating a region P of FIG. 1, and FIG. 16 is an enlarged view illustrating a region Q of FIG. 15.

Referring to FIGS. 1 and 2, a first semiconductor element layer 11 may be formed on a first substrate 10.

The first substrate 10 may include a first surface 10US and a second surface 10BS. The first surface 10US and the second surface 10BS may be disposed to be opposite to each other. The first semiconductor element layer 11 may be disposed on the first surface 10US of the first substrate 10. The first substrate 10 may have a first height H10a. For example, a distance between the first surface 10US and the second surface 10BS may be a first height H10a.

The first substrate 10 may be a silicon substrate or a silicon-on-insulator (SOI) substrate. Alternatively, the first substrate 10 may include, for example, silicon germanium, silicon germanium on insulator (SGOI), indium antimonide, lead telluride, indium arsenide, indium phosphide, gallium arsenide, or gallium antimonide, but is not limited thereto.

The first semiconductor element layer 11 may include a first semiconductor element. The first semiconductor element included in the first semiconductor element layer 11 may include, for example, a source/drain pattern 150, a source/drain contact 170, a contact connection via 180, a first wiring via 206, a first wiring line 207, a first insulating layer 110, and the like. The source/drain pattern 150, the source/drain contact 170, the contact connection via 180, the first wiring via 206, and the first wiring line 207 may be disposed in the first insulating layer 110.

For example, the first insulating layer 110 may include a first lower insulating layer 110a, a first intermediate insulating layer 110b, and a first upper insulating layer 110c. The source/drain pattern 150, the source/drain contact 170, and the contact connection via 180 may be disposed in the first lower insulating layer 110a. The first wiring via 206 may be disposed in the first intermediate insulating layer 110b. The first wiring line 207 may be disposed in the first upper insulating layer 110c. Although not shown in FIG. 2, the first semiconductor element layer 11 may include a gate electrode.

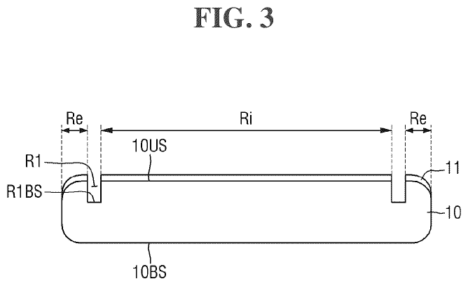

Referring to FIG. 3, a first recess R1 may be formed on the first substrate 10.

The first recess R1 may be formed on the first surface 10US of the first substrate 10. The first recess R1 may pass through the first surface 10US of the first substrate 10. The first recess R1 may pass through the first semiconductor element layer 11. The first recess R1 may pass through a portion of the first substrate 10. The first recess R1 may not completely pass through the first substrate 10. A bottom surface R1BS of the first recess R1 may be disposed in the first substrate 10. The bottom surface R1BS of the first recess R1 may be disposed between the first surface 10US and the second surface 10BS.

The first recess R1 may define an inner region Ri and an edge region Re of the first substrate 10. That is, the first substrate 10 may be divided into the inner region Ri and the edge region Re based on the first recess R1. The inner region Ri may be disposed inside the first recess R1. The edge region Re may be disposed outside the first recess R1. The first surface 10US and the second surface 10BS may be flat in the inner region Ri. The first surface 10US and the second surface 10BS may be curved in the edge region Re.

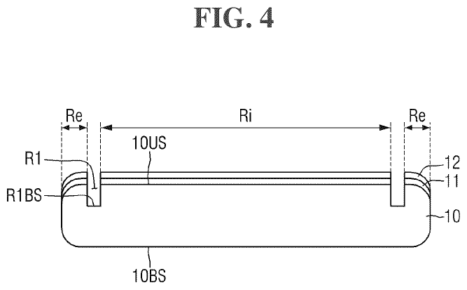

Referring to FIG. 4, an adhesive layer 12 may be formed on the first substrate 10.

The adhesive layer 12 may be formed on the first semiconductor element layer 11. The adhesive layer 12 may cover the first semiconductor element layer 11. The adhesive layer 12 may extend along the first semiconductor element layer 11. The first recess R1 may pass through the adhesive layer 12. The adhesive layer 12 may be disposed on the inner region Ri and the edge region Re of the first substrate 10.

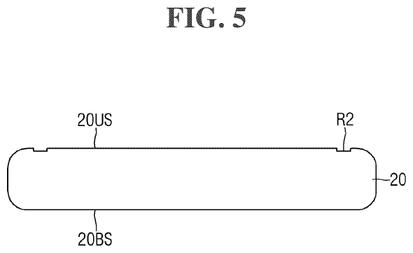

Referring to FIG. 5, a second recess R2 may be formed on a second substrate 20.

The second substrate 20 may include a third surface 20US and a fourth surface 20BS. The third surface 20US and the fourth surface 20BS may be disposed to be opposite to each other. The second recess R2 may be formed on the third surface 20US of the second substrate 20. The second recess R2 may pass through the third surface 20US of the second substrate 20. The second recess R2 may pass through a portion of the second substrate 20. A depth of the second recess R2 may be different from that of the first recess (R1 of FIG. 3). For example, the depth of the second recess R2 may be smaller than that of the first recess (R1 of FIG. 3), but example embodiments are not limited thereto.

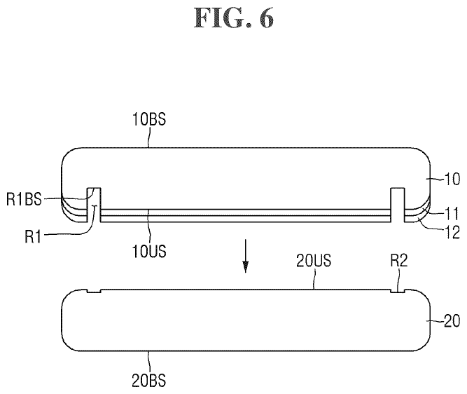

Referring to FIG. 6, the first substrate 10 may be adhered onto the second substrate 20.

The first surface 10US of the first substrate 10 and the third surface 20US of the second substrate 20 may face each other. The first recess R1 formed in the first substrate 10 and the second recess R2 formed in the second substrate 20 may be disposed to face each other. The first recess R1 formed in the first substrate 10 and the second recess R2 formed in the second substrate 20 may correspond to each other. The first substrate 10 and the second substrate 20 may be aligned using the first recess R1 formed in the first substrate 10 and the second recess R2 formed in the second substrate 20 as an overlay key. The first recess R1 and the second recess R2 may overlap each other, but example embodiments are not limited thereto. For example, the first recess R1 and the second recess R2 may not overlap each other.

The adhesive layer 12 disposed on the first substrate 10 may be disposed on the third surface 20US of the second substrate 20. The adhesive layer 12 may face the first surface 10US of the first substrate 10 and the third surface 20US of the second substrate 20. The adhesive layer 12 may be in contact with the third surface 20US of the second substrate 20.

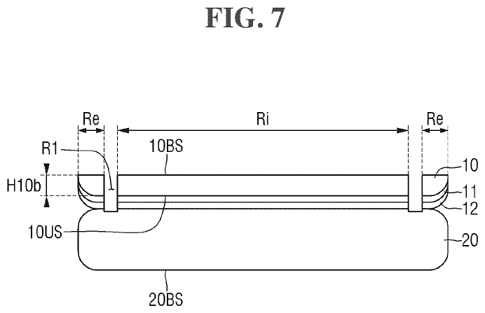

Referring to FIG. 7, a portion of the first substrate 10 may be removed from the second surface 10BS of the first substrate 10.

The first substrate 10 may have a second height H10b. For example, a distance between the first surface 10US and the second surface 10BS may be the second height H10b. Referring to FIG. 7 compared to FIG. 1, the second height H10b may be smaller than the first height H10a.

A portion of the first substrate 10 may be removed so that the first recess R1 is exposed on the second surface 10BS. A portion of the first substrate 10 may be removed from the second surface 10BS so that the bottom surface (R1BS of FIG. 6) of the first recess R1 is removed. The second surface 10BS may be flat. The second surface 10BS may be flat in the edge region Re. The first surface 10US may be curved in the edge region Re.

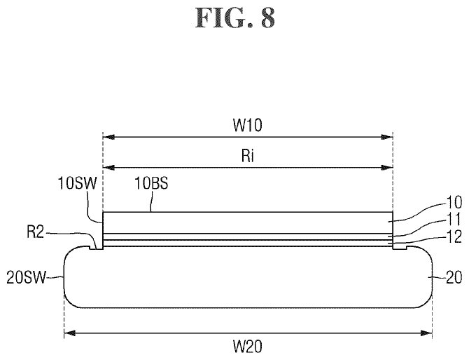

Referring to FIG. 8, the first substrate 10 of the edge region Re may be removed.

Only the inner region Ri of the first substrate 10 may remain. First sides 10SW of the first substrate 10 may be exposed while the edge region (Re of FIG. 7) is being removed. The first sides 10SW of the first substrate 10 may be flat. The second recess R2 of the second substrate 20 may be exposed while the edge region (Re of FIG. 7) is being removed, but example embodiments are not limited thereto. For example, when the first recess R1 does not overlap the second recess R2, the second recess R2 of the second substrate 20 may not be exposed while the edge region (Re of FIG. 7) is being removed.

The second substrate 20 may have a second width W20. The second substrate 20 may have second sides 20SW. The second sides 20SW may be curved. A distance between the outermost points of the second sides 20SW may be the second width W20.

The first substrate 10 may have a first width W10. In detail, the first substrate 10 of the inner region Ri may have the first width W10. A distance between the first sides 10SW of the first substrate 10 may be the first width W10. The first width W10 of the first substrate 10 may be smaller than the second width W20 of the second substrate 20.

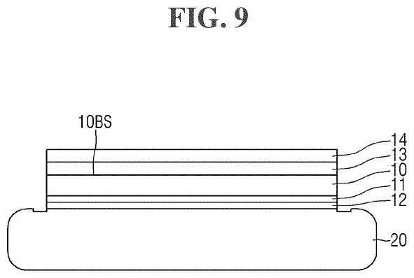

Referring to FIG. 9, a second semiconductor element layer 13 and a mask layer 14 may be formed on the first substrate 10.

In detail, the second semiconductor element layer 13 and the mask layer 14 may be sequentially formed on the second surface 10BS of the first substrate 10. The second semiconductor element layer 13 may extend along the second surface 10BS of the first substrate 10. The second semiconductor element layer 13 may cover the second surface 10BS of the first substrate 10. The second semiconductor clement layer 13 may include at least one of, for example, silicon oxide, silicon nitride, silicon oxynitride, or a low-k material.

The mask layer 14 may cover the second semiconductor element layer 13. The mask layer 14 may extend along the second semiconductor element layer 13. The mask layer 14 may include, for example, a photoresist material.

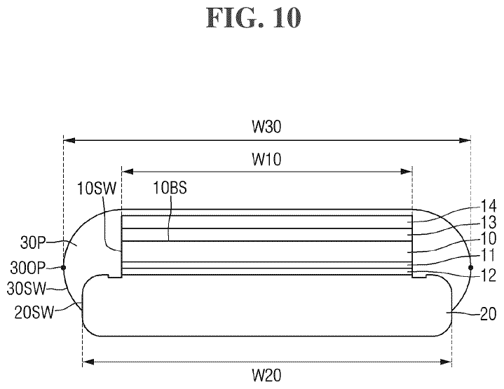

Referring to FIG. 10, a pre-passivation layer 30P may be formed.

The pre-passivation layer 30P may cover the sides 10SW of the first substrate 10. The pre-passivation layer 30P may surround the sides 10SW of the first substrate 10. The pre-passivation layer 30P may cover the mask layer 14 disposed on the first substrate 10. A thickness of the pre-passivation layer 30P disposed on the second surface 10BS of the first substrate 10 may be smaller than a thickness of the pre-passivation layer 30P disposed on the first sides 10SW of the first substrate 10. That is, a thickness from an upper surface of the mask layer 14 to an upper surface of the pre-passivation layer 30P may be smaller than a thickness from the first sides 10SW of the first substrate 10 to an outermost point 30OP of third sides 30SW of the pre-passivation layer 30P.

The pre-passivation layer 30P may have the third sides 30SW. The third sides 30SW may be curved. The third sides 30SW of the pre-passivation layer 30P may have the outermost points 30OP. The outermost points 30OP may refer to points most outwardly protruded from the third sides 30SW. The pre-passivation layer 30P may have a third width W30. A distance between the outermost points 30OP of the third sides 30SW may be the third width W30. The third width W30 may be greater than the first width W10 and the second width W20. The outermost points 30OP of the third sides 30SW may protrude outwardly more than the first sides 10SW of the first substrate 10 and the second sides 20SW of the second substrate 20.

The pre-passivation layer 30P may cover a portion of the second sides 20SW of the second substrate 20. The pre-passivation layer 30P also may be formed on the second sides 20SW of the second substrate 20.

The pre-passivation layer 30P may include, for example, a photoresist material. The pre-passivation layer 30P may include a material different from that of the mask layer 14.

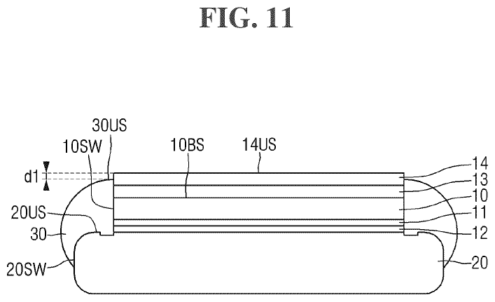

Referring to FIG. 11, the pre-passivation layer (30P of FIG. 10) formed on an upper surface 14US of the mask layer 14 is removed, and a passivation layer 30 may be formed. The passivation layer 30 may be formed by removing the pre-passivation layer (30P of FIG. 10) on the upper surface 14US of the mask layer 14.

While the pre-passivation layer (30P of FIG. 10) formed on the upper surface of the mask layer 14 is removed, the upper surface 14US of the mask layer 14 may be exposed. The passivation layer 30 may not cover the second surface 10BS of the first substrate 10. The passivation layer 30 may not be formed on the second surface 10BS of the first substrate 10. The passivation layer 30 may not vertically overlap the second surface 10BS of the first substrate 10. The passivation layer 30 may cover the first sides 10SW of the first substrate 10.

An uppermost surface 30US of the passivation layer 30 may be disposed above the second surface 10BS of the first substrate 10. That is, a height of the uppermost surface 30US of the passivation layer 30 may be greater than that of the second surface 10BS of the first substrate 10 based on the upper surface 20US of the second substrate 20.

The uppermost surface 30US of the passivation layer 30 may be disposed below the upper surface 14US of the mask layer 14. A distance between the uppermost surface 30US of the passivation layer 30 and the upper surface 14US of the mask layer 14 may be a first distance d1. A step difference may be formed between the uppermost surface 30US of the passivation layer 30 and the upper surface 14US of the mask layer 14. The passivation layer 30 may cover only a portion of sides of the mask layer 14.

In FIG. 11, the uppermost surface 30US of the passivation layer 30 is shown as being disposed below the upper surface 14US of the mask layer 14, but example embodiments are not limited thereto. For example, the uppermost surface 30US of the passivation layer 30 may be disposed on the same plane as the upper surface 14US of the mask layer 14. For another example, the uppermost surface 30US of the passivation layer 30 may be disposed above the upper surface 14US of the mask layer 14.

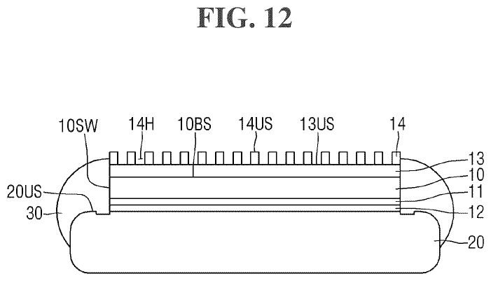

Referring to FIG. 12, the mask layer 14 may be patterned.

For example, a mask hole 14H may be formed in the mask layer 14. The second semiconductor element layer 13 may be exposed into the mask hole 14H. The upper surface 13US of the second semiconductor element layer 13 may be exposed through the mask hole 14H.

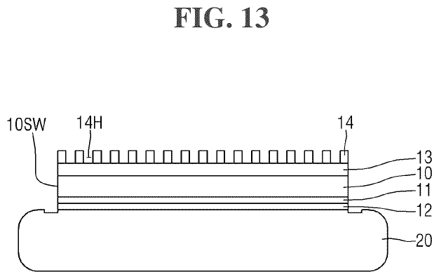

Referring to FIG. 13, the passivation layer 30 may be removed.

For example, the passivation layer 30 may be exposed and removed through a photo process. Since the passivation layer 30 includes a material different from that of the mask layer 14, the mask layer 14 exposed together with the passivation layer 30 may not be removed when the passivation layer 30 is removed. As the passivation layer 30 is removed, the first sides 10SW of the first substrate 10 may be exposed.

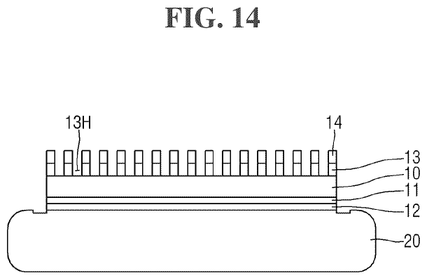

Referring to FIG. 14, the second semiconductor element layer 13 may be patterned.

The second semiconductor element layer 13 may be patterned using the patterned mask layer 14 as a mask. An element hole 13H may be formed in the second semiconductor element layer 13.

Referring to FIG. 12, when the passivation layer 30 is not disposed on the first sides 10SW of the first substrate 10, a step difference may occur between the first substrate 10 and the second substrate 20. For example, a step difference may occur between the mask layer 14 on the first substrate 10 and the third surface 20US of the second substrate 20. When the mask layer 14 is patterned in the edge region of the first substrate 10 having a step difference from the second substrate 20, the mask layer 14 of the edge region may not be stably patterned. For example, the mask layer 14 patterned onto the second substrate 20 may be tilted.

On the other hand, the step difference between the first substrate 10 and the second substrate 20 may be reduced when the passivation layer 30 is disposed on the first sides 10SW of the first substrate 10. For example, as the passivation layer 30 is disposed between the upper surface of the mask layer 14 on the first substrate 10 and the third surface 20US of the second substrate 20, the step difference between the upper surface of the mask layer 14 on the first substrate 10 and the third surface 20US of the second substrate 20 may be supplemented. Therefore, the mask layer 14 may be stably patterned even in the edge region having a step difference.

Referring to FIGS. 15 and 16, the mask layer 14 may be removed, and a second semiconductor element 135 may be formed in the second semiconductor element layer 13.

The second semiconductor element 135 may be formed on the second surface 10BS of the first substrate 10. The second semiconductor element 135 may be formed over the second semiconductor element layer 13 and the first substrate 10.

The second semiconductor element 135 may be connected to the first semiconductor element of the first semiconductor element layer 11. The second semiconductor element 135 may be electrically connected to the first semiconductor element of the first semiconductor clement layer 11. For example, the second semiconductor element 135 may be connected to the contact connection via 180. The second semiconductor element 135 may include, for example, a power supply wiring line.

Then, the first substrate 10 and the second substrate 20 may be separated from each other. The first substrate 10 adhered onto the second substrate 20 may be separated from the second substrate 20. The first substrate 10, the first semiconductor element layer 11 and the second semiconductor element layer 13 may be separated from the second substrate 20 and the adhesive layer 12.

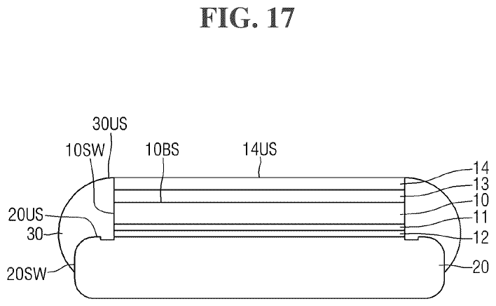

FIG. 17 is a view illustrating intermediate operations to describe a method for fabricating a semiconductor device according to some other embodiments of the present disclosure. For convenience of description, the following description will be based on differences from FIG. 11. For reference, FIG. 17 is a view illustrating operations subsequent to FIG. 10.

Referring to FIG. 17, the uppermost surface 30US of the passivation layer 30 may be disposed on the same plane as the upper surface 14US of the mask layer 14.

The passivation layer 30 may cover the entire sides of the mask layer 14. A step difference may not be formed between the uppermost surface 30US of the passivation layer 30 and the upper surface 14US of the mask layer 14.

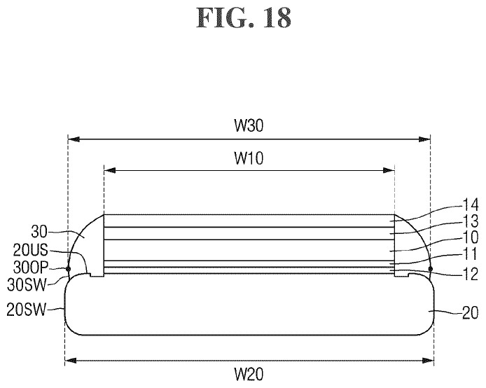

FIG. 18 is a view illustrating intermediate operations to describe a method for fabricating a semiconductor device according to some other embodiments of the present disclosure. For convenience of description, the following description will be based on differences from the description made with reference to FIG. 17. For reference, FIG. 18 is a view illustrating operations subsequent to FIG. 10.

Referring to FIG. 18, the passivation layer 30 may not be formed on the sides 20SW of the second substrate 20. That is, the passivation layer 30 may not cover the sides 20SW of the second substrate 20. The passivation layer 30 may not overlap the sides 20SW of the second substrate 20 in a horizontal direction. The passivation layer 30 may be formed on the second substrate 20.

A third width W30 between the outermost points 30OP of the third sides 30SW of the passivation layer 30 may be smaller than the second width W20 of the second substrate 20. The third width W30 between the outermost points 30OP of the third sides 30SW of the passivation layer 30 may be greater than the first width W10 of the first substrate 10.

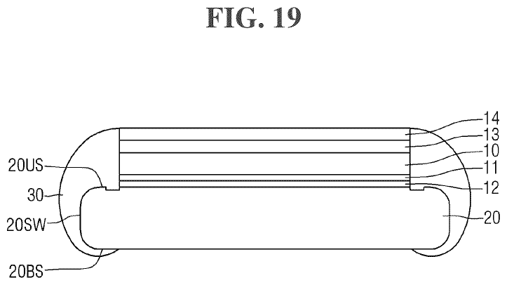

FIG. 19 is a view illustrating intermediate operations to describe a method for fabricating a semiconductor device according to some other embodiments of the present disclosure. For convenience of description, the following description will be based on differences from the description made with reference to FIG. 17. For reference, FIG. 19 is a view illustrating operations subsequent to FIG. 10.

Referring to FIG. 19, the passivation layer 30 also may be formed below the second substrate 20. The passivation layer 30 may be formed on the fourth surface 20BS of the second substrate 20. The passivation layer 30 may cover a portion of the fourth surface 20BS of the second substrate 20. The passivation layer 30 may surround the entire second sides 20SW of the second substrate 20.

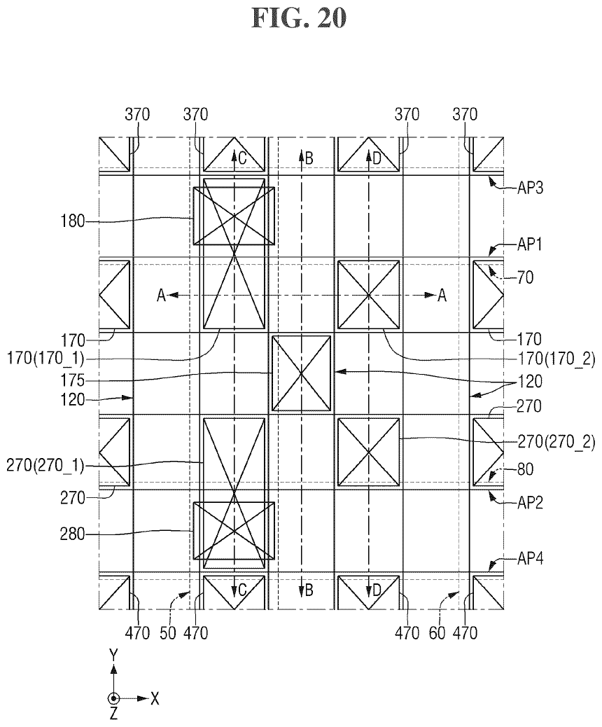

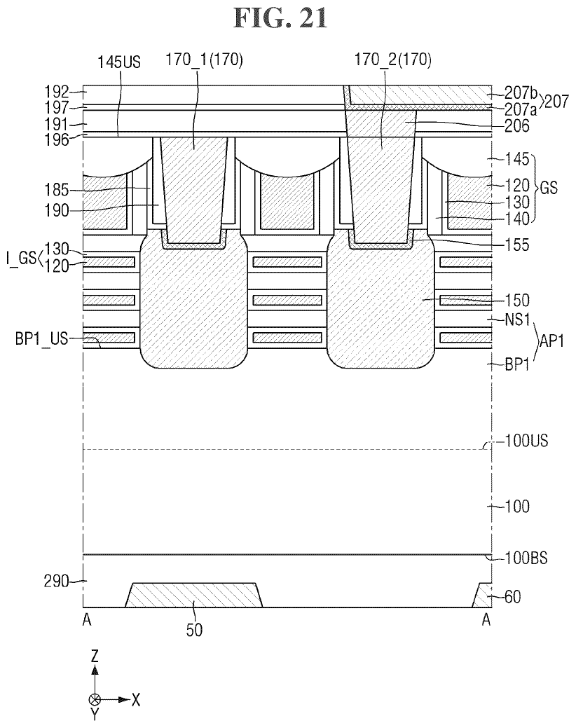

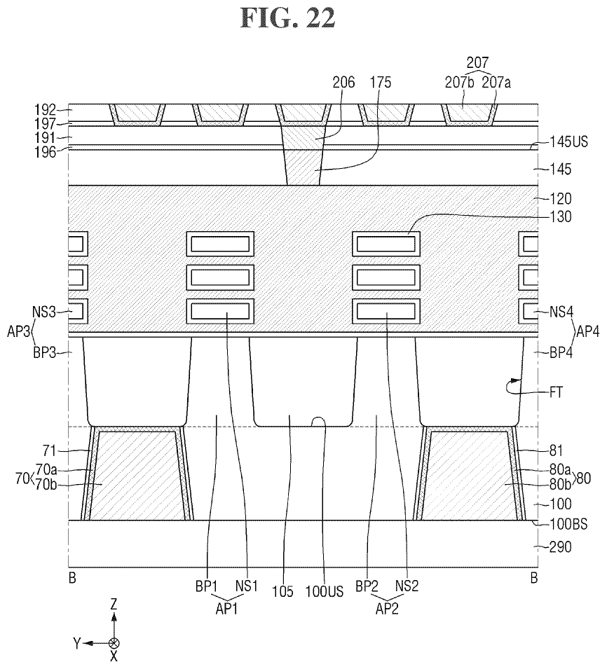

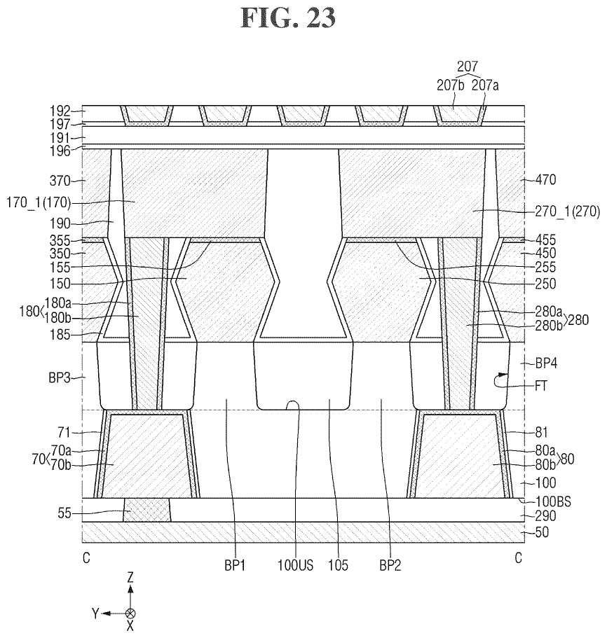

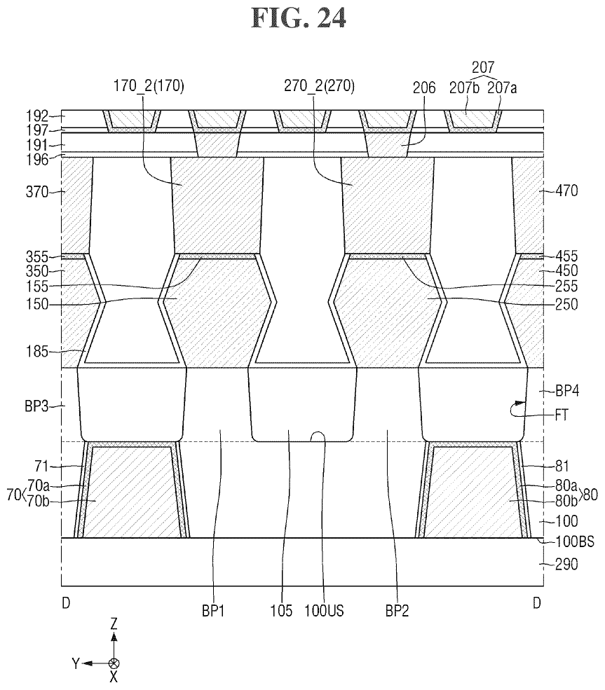

FIG. 20 is a layout view illustrating a semiconductor device according to some embodiments of the present disclosure. FIG. 21 is a cross-sectional view taken along line A-A of FIG. 20. FIG. 22 is a cross-sectional view taken along line B-B of FIG. 20. FIG. 23 is a cross-sectional view taken along line C-C of FIG. 20. FIG. 24 is a cross-sectional view taken along line D-D of FIG. 20.

Referring to FIGS. 20 to 24, a semiconductor device according to some embodiments may include a substrate 100, a first active pattern AP1, a second active pattern AP2, a third active pattern AP3, a fourth active pattern AP4, a first rear wiring line 50, a second rear wiring line 60, a first buried conductive pattern 70, a second buried conductive pattern 80, a plurality of gate electrodes 120, a first source/drain pattern 150, a second source/drain pattern 250, a third source/drain pattern 350, a fourth source/drain pattern 450, a first source/drain contact 170, a second source/drain contact 270, a third source/drain contact 370, a fourth source/drain contact 470, a first contact connection via 180, a second contact connection via 280, and a source/drain etch stop layer 185.

The substrate 100 may correspond to the first substrate (10 of FIG. 15) described with reference to FIGS. 1 to 19. The first active pattern AP1, the second active pattern AP2, the third active pattern AP3, the fourth active pattern AP4, the plurality of gate electrodes 120, the first source/drain pattern 150, the second source/drain pattern 250, the third source/drain pattern 350, the fourth source/drain pattern 450, the first source/drain contact 170, the second source/drain contact 270, the third source/drain contact 370, the fourth source/drain contact 470, the first contact connection via 180, and the second contact connection via 280 may correspond to the first semiconductor element of the first semiconductor element layer (11 of FIG. 15) described with reference to FIGS. 1 to 19. The first rear wiring line 50, the second rear wiring line 60, the first buried conductive pattern 70 and the second buried conductive pattern 80 may correspond to the second semiconductor element (135 of FIG. 15) of the second semiconductor element layer (13 of FIG. 15) described with reference to FIGS. 1 to 19.

The substrate 100 may include a first surface 100US and a second surface 100BS, which are opposite to each other in a third direction Z. Since the gate electrode 120 and the source/drain patterns 150, 250, 350 and 450 may be disposed on the first surface 100US of the substrate, the first surface 100US of the substrate may be an upper surface of the substrate 100. The second surface 100BS of the substrate opposite to the first surface 100US of the substrate may be a lower surface of the substrate 100.

The substrate 100 may be a semiconductor material, or may include a semiconductor material. The substrate 100 may be a silicon substrate or a silicon-on-insulator (SOI) substrate. Alternatively, the substrate 100 may include, for example, silicon germanium, silicon germanium on insulator (SGOI), indium antimonide, lead telluride, indium arsenide, indium phosphide, gallium arsenide or gallium antimonide, but is not limited thereto.

Each of the active patterns AP1, AP2, AP3 and AP4 may be disposed on the substrate 100. For example, each of the active patterns AP1, AP2, AP3 and AP4 may be disposed on the first surface 100US of the substrate. Each of the active patterns AP1, AP2, AP3 and AP4 may be elongated in a first direction X.

The first active pattern AP1 may be spaced apart from the second active pattern AP2 and the third active pattern AP3 in a second direction Y. The second active pattern AP2 may be spaced apart from the fourth active pattern AP4 in the second direction Y. For example, the first active pattern AP1 and the second active pattern AP2 may be adjacent to each other in the second direction Y.

For example, one of the first active pattern AP1 and the second active pattern AP2 may be a region in which a p-type transistor is formed, and the other one thereof may be a region in which an n-type transistor is formed. In this case, the first active pattern AP1 and the third active pattern AP3 may be regions in which transistors of the same conductivity type are formed. The second active pattern AP2 and the fourth active pattern AP4 may be regions in which transistors of the same conductivity type are formed.

For another example, the first active pattern AP1 and the second active pattern AP2 may be regions in which a p-type transistor is formed. In this case, the third active pattern AP3 and the fourth active pattern AP4 may be regions in which an n-type transistor is formed.

For another example, the first active pattern AP1 and the second active pattern AP2 may be regions in which an n-type transistor is formed. The third active pattern AP3 and the fourth active pattern AP4 may be regions in which a p-type transistor is formed.

Each of the active patterns AP1, AP2, AP3, and AP4 may be a multi-channel active pattern. For example, the first active pattern AP1 may include a first lower pattern BP1 and a plurality of first sheet patterns NS1. The second active pattern AP2 may include a second lower pattern BP2 and a plurality of second sheet patterns NS2. The third active pattern AP3 may include a third lower pattern BP3 and a plurality of third sheet patterns NS3. The fourth active pattern AP4 may include a fourth lower pattern BP4 and a plurality of fourth sheet patterns NS4. In the semiconductor device according to some embodiments, each of the active patterns AP1, AP2, AP3 and AP4 may be an active pattern that includes nanosheets or nanowires.

Each of the lower patterns BP1, BP2, BP3 and BP4 may protrude from the substrate 100. For example, each of the lower patterns BP1, BP2, BP3 and BP4 may protrude from the first surface 100US of the substrate. Each of the lower patterns BP1, BP2, BP3 and BP4 may be a fin-type pattern.

Each of the lower patterns BP1, BP2, BP3 and BP4 may be elongated in the first direction X. The first lower pattern BP1 may be spaced apart from the second lower pattern BP2 and the third lower pattern BP3 in the second direction Y. The second lower pattern BP2 may be spaced apart from the fourth lower pattern BP4 in the second direction Y.

Each of the lower patterns BP1, BP2, BP3 and BP4 may be separated by a fin trench FT extended in the first direction X. For example, the first surface 100US of the substrate may be a bottom surface of the fin trench FT. Each of the lower patterns BP1, BP2, BP3 and BP4 includes sidewalls extended in the first direction X. The sidewalls of each of the lower patterns BP1, BP2, BP3 and BP4 may be defined by the fin trench FT.

The plurality of first sheet patterns NS1 may be disposed on the first lower pattern BP1. The plurality of first sheet patterns NS1 may be spaced apart from an upper surface BP1_US of the first lower pattern in the third direction Z. The plurality of first sheet patterns NS1 may be disposed on the first surface 100US of the substrate.

The plurality of second sheet patterns NS2 may be disposed on the second lower pattern BP2. The plurality of second sheet patterns NS2 may be spaced apart from the second lower pattern BP2 in the third direction Z. The plurality of third sheet patterns NS3 may be disposed on the third lower pattern BP3. The plurality of third sheet patterns NS3 may be spaced apart from the third lower pattern BP3 in the third direction Z. The plurality of fourth sheet patterns NS4 may be disposed on the fourth lower pattern BP4. The plurality of fourth sheet patterns NS4 may be spaced apart from the fourth lower pattern BP4 in the third direction Z. The second to fourth sheet patterns NS2, NS3 and NS4 may be disposed on the first surface 100US of the substrate.

In this case, the first direction X may cross the second direction Y and the third direction Z. In addition, the second direction Y may cross the third direction Z. The third direction Z may be a thickness direction of the substrate 100.

Each of the sheet patterns NS1, NS2, NS3 and NS4 may include an upper surface and a lower surface, which are opposite to each other in the third direction Z. The lower surfaces of the sheet patterns NS1, NS2, NS3 and NS4 may face the substrate 100, respectively. Each of the sheet patterns NS1, NS2, NS3 and NS4 is shown as being disposed as three in the third direction Z, but this is for convenience of description, and the present disclosure is not limited thereto.

Each of the sheet patterns NS1, NS2, NS3 and NS4 may include an uppermost sheet pattern farthest away from the substrate 100. For example, the upper surfaces of the active patterns AP1, AP2, AP3, and AP4 may be the upper surfaces of the uppermost sheet pattern among the sheet patterns NS1, NS2, NS3 and NS4.

Each of the lower patterns BP1, BP2, BP3 and BP4 may be formed by etching a portion of the substrate 100 or may include an epitaxial layer grown from the substrate 100. Each of the lower patterns BP1, BP2, BP3 and BP4 may include silicon or germanium, which is an elemental semiconductor material. In addition, each of the lower patterns BP1, BP2, BP3 and BP4 may include a compound semiconductor, and may include, for example, a group IV-IV compound semiconductor or a group III-V compound semiconductor.

The group IV-IV compound semiconductor may be a binary compound or ternary compound, which includes at least two of carbon (C), silicon (Si), germanium (Ge) or tin (Sn), or a compound including at least two of carbon (C), silicon (Si), germanium (Ge) or tin (Sn), which are doped with a group IV element.

The group III-V compound semiconductor may be, for example, one of a binary compound, a ternary compound or a quaternary compound, which is formed by combination of at least one of aluminum (Al), gallium (Ga) or indium (In), which is a group III element, and one of phosphorus (P), arsenic (As) and antimony (Sb), which are group V elements.

Each of the sheet pattern NS1, NS2, NS3 and NS4 may include one of silicon or germanium, which is an elemental semiconductor material, group IV-IV compound semiconductor, or group III-V compound semiconductor. For example, a width of the first sheet pattern NS1 in the second direction Y may be increased or reduced in proportion to that of the first lower pattern BP1 in the second direction Y. The respective widths of the first sheet patterns NS1 disposed on the first lower pattern BPI are shown as being the same as each other in the second direction Y, but are not limited thereto.

A field insulating layer 105 is disposed on the substrate 100. For example, the field insulating layer 105 may be disposed on the first surface 100US of the substrate. The field insulating layer 105 may fill at least a portion of the fin trench FT for separating the lower patterns BP1, BP2, BP3 and BP4.

The field insulating layer 105 may be disposed on the substrate 100 among the lower patterns BP1, BP2, BP3 and BP4. For example, the field insulating layer 105 may cover the entire sidewalls of the lower patterns BP1, BP2, BP3 and BP4. Unlike the shown example, as another example, the field insulating layer 105 may cover a portion of the sidewalls of the lower pattern BP1, BP2, BP3 and BP4. In this case, a portion of the lower patterns BP1, BP2, BP3 and BP4 may protrude more in the third direction Z than an upper surface of the field insulating layer 105.

The field insulating layer 105 does not cover the upper surface BP1_US of the first lower pattern. The field insulating layer 105 does not cover the upper surfaces of the second to fourth lower patterns BP2, BP3 and BP4. Each of the sheet patterns NS1, NS2, NS3 and NS4 is disposed to be higher than the upper surface of the field insulating layer 105 based on the first surface 100US of the substrate.

The field insulating layer 105 may include, for example, an oxide layer, a nitride layer, an oxynitride layer, or their combination layer. The field insulating layer 105 is shown as a single layer, but this is for convenience of description and the present disclosure is not limited

A plurality of gate structures GS may be disposed on the first surface 100US of the substrate. Each of the gate structures GS may extend in the second direction Y. The gate structures GS may be disposed to be spaced apart from each other in the first direction X. The gate structures GS may be adjacent to each other in the first direction X.

The gate structures GS may be disposed on each of the active patterns AP1, AP2, AP3, and AP4. For example, the gate structures GS may cross the first active pattern AP1 and the second active pattern AP2.

The gate structure GS may cross the first lower pattern BP1 and the second lower pattern BP2. The gate structure GS may surround each of the first sheet patterns NS1. The gate structures GS may surround each of the second sheet patterns NS2.

The gate structures GS may cross the third lower pattern BP3 and the fourth lower pattern BP4. The gate structures GS may surround each of the third sheet pattern NS3. The gate structures GS may surround each of the fourth sheet patterns NS4. The gate structures GS are shown as being disposed over the first to fourth active patterns AP1, AP2, AP3 and AP4, but are not limited thereto.

The gate structures GS may include, for example, a gate electrode 120, a gate insulating layer 130, a gate spacer 140, and a gate capping layer 145.

The gate structures GS may include a plurality of inner gate structures I_GS disposed between the first sheet patterns NS1 adjacent to each other in the third direction Z and between the first lower pattern BP1 and the first sheet pattern NS1. The inner gate structures I_GS may be disposed between the upper surface BP1_US of the first lower pattern and the lower surface of the first sheet pattern NS1 and between the upper surface of the first sheet pattern NS1 and the lower surface of the first sheet pattern NS1, which face each other in the third direction Z.

The number of inner gate structures I_GS may be the same as the number of first sheet patterns NS1. The inner gate structures I_GS are in contact with the upper surface BP1_US of the first lower pattern, the upper surface of the first sheet pattern NS1 and the lower surface of the first sheet pattern NS1. In the semiconductor device according to some embodiments, the inner gate structure I_GS may be in contact with the first source/drain pattern 150 that will be described later.

The inner gate structure I_GS includes a gate electrode 120 and a gate insulating layer 130, which are disposed between adjacent first sheet patterns NS1 and between the first lower pattern BP1 and the first sheet pattern NS1. Although not shown, the inner gate structure I_GS may be disposed between the second sheet patterns NS2 adjacent to each other in the third direction Z and between the second lower pattern BP2 and the second sheet pattern NS2. The inner gate structure I_GS may be disposed between the third sheet patterns NS3 adjacent to each other in the third direction Z and between the third lower pattern BP3 and the third sheet pattern NS3. The inner gate structure I_GS may be disposed between the fourth sheet patterns NS4 adjacent to each other in the third direction Z and between the fourth lower pattern BP4 and the fourth sheet pattern NS4.

The following description will be based on the first active pattern AP1, the gate structure GS, the second active pattern AP2 and the gate structure GS.

The gate electrode 120 may be disposed on the first lower pattern BP1 and the second lower pattern BP2. The gate electrode 120 may cross the first lower pattern BP1 and the second lower pattern BP2. The gate electrode 120 may surround the first sheet pattern NS1 and the second sheet pattern NS2.

In the cross-sectional view as in FIG. 21, an upper surface of the gate electrode 120 is shown as being a concave curved surface, but is not limited thereto. The upper surface of the gate electrode 120 may be planar.

The gate electrode 120 may include at least one of a metal, a metal alloy, a conductive metal nitride, a metal silicide, a doped semiconductor material, a conductive metal oxide or a conductive metal oxynitride. The gate electrode 120 may include at least one of, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or their combination, but is not limited thereto. The conductive metal oxide and the conductive metal oxynitride may include an oxidized form of the above-described materials, but are not limited thereto.

The gate insulating layer 130 may extend along the upper surface of the field insulating layer 105, the upper surface BP1_US of the first lower pattern and the upper surface of the second lower pattern BP2. The gate insulating layer 130 may surround the plurality of first sheet patterns NS1. The gate insulating layer 130 may surround the plurality of second sheet patterns NS2. The gate insulating layer 130 may be disposed along the periphery of the first sheet patterns NS1 and the periphery of the second sheet patterns NS2. The gate electrode 120 is disposed on the gate insulating layer 130.

The gate insulating layer 130 is disposed between the gate electrode 120 and the first sheet pattern NS1 and between the gate electrode 120 and the second sheet pattern NS2. In the semiconductor device according to some embodiments, the gate insulating layer 130 included in the inner gate structure I_GS may be in contact with the first source/drain pattern 150 that will be described later.

The gate insulating layer 130 may include silicon oxide, silicon oxide, silicon oxynitride, silicon nitride, or a high-k material having a dielectric constant greater than that of silicon oxide. The high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide or lead zinc niobate.

The gate insulating layer 130 is shown as a single layer, but this is for convenience of description and is not limited thereto. The gate insulating layer 130 may include a plurality of layers. For example, the gate insulating layer 130 may include an interfacial layer disposed between the first active pattern AP1 and the gate electrode 120 and between the second active pattern AP2 and the gate electrode 120, and a high-k insulating layer. For example, the interfacial layer may not be formed along a profile of the upper surface of the field insulating layer 105.

The semiconductor device according to some embodiments may include a negative capacitance (NC) FET based on a negative capacitor. For example, the gate insulating layer 130 may include a ferroelectric material layer having ferroelectric characteristics and a paraelectric material layer having paraelectric characteristics.

The ferroelectric material layer may have a negative capacitance, and the paraelectric material layer may have a positive capacitance. For example, when two or more capacitors are connected in series, and the capacitance of each capacitor has a positive value, the total capacitance is more reduced than the capacitance of each individual capacitor. On the other hand, when at least one of capacitances of two or more capacitors connected in series has a negative value, the total capacitance may have a positive value and may be greater than an absolute value of each individual capacitance.

When a ferroelectric material layer having a negative capacitance and a paraelectric material layer having a positive capacitance are connected in series, the total capacitance value of the ferroelectric material layer and the paraelectric material layer, which are connected in series, may be increased. Based on the total capacitance value that is increased, a transistor having a ferroelectric material layer may have a subthreshold swing (SS) less than 60 mV/decade at a room temperature.

The ferroelectric material layer may have ferroelectric characteristics. The ferroelectric material layer may include at least one of, for example, hafnium oxide, hafnium zirconium oxide, barium strontium titanium oxide, barium titanium oxide, or lead zirconium titanium oxide. In this case, for example, the hafnium zirconium oxide may be a material doped with zirconium (Zr) in hafnium oxide. For another example, the hafnium zirconium oxide may be a compound of hafnium (Hf) and zirconium (Zr) and oxygen (O).

The ferroelectric material layer may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material layer may be varied depending on the ferroelectric material of the ferroelectric material layer.

When the ferroelectric material layer includes hafnium oxide, the dopant included in the ferroelectric material layer may include at least one of gadolinium (Gd), silicon (Si), zirconium (Zr), aluminum (Al), or yttrium (Y).

When the dopant is aluminum (Al), the ferroelectric material layer may include aluminum of 3 at % to 8 at % (atomic %). In this case, a ratio of the dopant may be a ratio of aluminum to a sum of hafnium and aluminum.

When the dopant is silicon (Si), the ferroelectric material layer may include silicon of 2 at % to 10 at %. When the dopant is yttrium (Y), the ferroelectric material layer may include yttrium of 2 at % to 10 at %. When the dopant is gadolinium (Gd), the ferroelectric material layer may include gadolinium of 1 at % to 7 at %. When the dopant is zirconium (Zr), the ferroelectric material layer may include zirconium of 50 at % to 80 at %.

The paraelectric material layer may have paraelectric characteristics. The paraelectric material layer may include at least one of, for example, silicon oxide or metal oxide having a high dielectric constant. The metal oxide included in the paraelectric material layer may include, but is not limited to, at least one of hafnium oxide, zirconium oxide, or aluminum oxide.

The ferroelectric material layer and the paraelectric material layer may include the same material. Although the ferroelectric material layer has ferroelectric characteristics, the paraelectric material layer may not have ferroelectric characteristics. For example, when the ferroelectric material layer and the paraelectric material layer include hafnium oxide, a crystal structure of hafnium oxide included in the ferroelectric material layer is different from that of hafnium oxide included in the paraelectric material layer.

The ferroelectric material layer may have a thickness having ferroelectric characteristics. The thickness of the ferroelectric material layer may be, for example, 0.5 nm to 10 nm, but is not limited thereto. Since a threshold thickness indicating ferroelectric characteristics may vary depending on each ferroelectric material, the thickness of the ferroelectric material layer may vary depending on the ferroelectric material.

For example, the gate insulating layer 130 may include one ferroelectric material layer. For another example, the gate insulating layer 130 may include a plurality of ferroelectric material layers spaced apart from each other. The gate insulating layer 130 may have a stacked layer structure in which a plurality of ferroelectric material layers and a plurality of paraelectric material layers are alternately stacked.

The gate spacer 140 may be disposed on the sidewalls of the gate electrode 120. For example, the gate spacer 140 may not be disposed between the first lower pattern BP1 and the first sheet pattern NS1 and between the first sheet patterns NS1 adjacent to each other in the third direction Z.

The gate spacer 140 may include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) or their combination. The gate spacer 140 is shown as a single layer, but is only for convenience of description and is not limited thereto.

The gate capping layer 145 may be disposed on the gate electrode 120. An upper surface of the gate capping layer 145 may be an upper surface of the gate structure GS. Unlike the shown example, the gate capping layer 145 may be disposed between the gate spacers 140.

The gate capping layer 145 may include at least one of, for example, silicon nitride (SiN), silicon oxynitride (SiON), silicon carbonitride (SiCN), silicon oxycarbonitride (SiOCN) or their combination.

The first source/drain pattern 150 may be disposed on the first active pattern AP1. The first source/drain pattern 150 may be disposed on the first lower pattern BP1. The first source/drain pattern 150 may be disposed between the gate electrodes 120 adjacent to each other in the first direction X. The first source/drain pattern 150 may be in contact with the first active pattern AP1. The first source/drain pattern 150 may be in contact with the first sheet pattern NS1. The first source/drain pattern 150 is connected to the first sheet pattern NS1 and the first lower pattern BP1 on the first surface 100US of the substrate.

The second source/drain pattern 250 may be disposed on the second active pattern AP2. The second source/drain pattern 250 may be disposed on the second lower pattern BP2. The second source/drain pattern 250 may be disposed between the gate electrodes 120 adjacent to each other in the first direction X. The second source/drain pattern 250 may be in contact with the second active pattern AP2. Although not shown, the second source/drain pattern 250 may be in contact with the second sheet pattern NS2. The second source/drain pattern 250 is connected to the second sheet pattern NS2 and the second lower pattern BP2 on the first surface 100US of the substrate.

The third second source/drain pattern 350 may be disposed on the third active pattern AP3. The third source/drain pattern 350 may be disposed on the third lower pattern BP3. Although not shown, the third source/drain pattern 350 may be in contact with the third sheet pattern NS3. The fourth source/drain pattern 450 may be disposed on the fourth active pattern AP4. The fourth source/drain pattern 450 may be disposed on the fourth lower pattern BP4. Although not shown, the fourth source/drain pattern 450 may be in contact with the fourth sheet pattern NS4.

The source/drain patterns 150, 250, 350 and 450 may include bottom surfaces facing the lower patterns BP1, BP2, BP3 and BP4, and sidewalls extended in the third direction Z from the bottom surfaces of the source/drain patterns 150, 250, 350 and 450. The sidewalls of the source/drain patterns 150, 250, 350 and 450 may include facet crossing points where inclined surfaces meet, but are not limited thereto.

The first source/drain pattern 150 may be included in a source/drain of a transistor that uses the first sheet pattern NS1 as a channel region. The second source/drain pattern 250 may be included in a source/drain of a transistor that uses the second sheet pattern NS2 as a channel region. The third source/drain pattern 350 may be included in a source/drain of a transistor that uses the third sheet pattern NS3 as a channel region. The fourth source/drain pattern 450 may be included in a source/drain of a transistor that uses the fourth sheet pattern NS4 as a channel region.

Each of the source/drain patterns 150, 250, 350 and 450 may include an epitaxial pattern. Each of the source/drain patterns 150, 250, 350 and 450 may include a semiconductor material.

Some of the source/drain patterns 150, 250, 350 and 450 may include a p-type dopant. The p-type dopant may include, but is not limited to, at least one of boron (B) or gallium (Ga). The rest of the source/drain patterns 150, 250, 350 and 450 may include an n-type dopant. The n-type dopant may include at least one of phosphorus (P), arsenic (As), antimony (Sb), or bismuth (Bi), but is not limited thereto.

The source/drain etch stop layer 185 may extend along outer sidewalls of the gate spacer 140 and sidewalls of the source/drain patterns 150, 250, 350 and 450. The source/drain etch stop layer 185 may extend along the upper surface of the field insulating layer 105.

The source/drain etch stop layer 185 may not extend along sidewalls of the gate capping layer 145. Unlike the shown example, the source/drain etch stop layer 185 may extend along the sidewalls of the gate capping layer 145.

The source/drain etch stop layer 185 may include at least one of, for example, silicon nitride (SiN), silicon oxynitride (SiON), silicon oxycarbonitride (SiOCN), silicon boron nitride (SiBN), silicon oxyboron nitride (SiOBN), silicon oxycarbide (SiOC) or their combination.

A first upper interlayer insulating layer 190 is disposed on the first surface 100US of the substrate. The first upper interlayer insulating layer 190 may be disposed on the source/drain patterns 150, 250, 350 and 450.

The first upper interlayer insulating layer 190 may not cover the upper surface of the gate capping layer 145. The first upper interlayer insulating layer 190 may include at least one of, for example, silicon oxide, silicon nitride, silicon oxynitride, or a low-k material. A dielectric constant of the low-k material may have a value smaller than 3.9 that is the dielectric constant of the silicon oxide.

The first source/drain contact 170 may extend in the third direction Z on the first surface 100US of the substrate. The first source/drain contact 170 may be disposed on the first source/drain pattern 150. The first source/drain contact 170 is electrically connected to the first source/drain pattern 150.

The first source/drain contact 170 may include a first rear connection contact 170_1 and a first front connection contact 170_2. The first rear connection contact 170_1 may be connected to the first buried conductive pattern 70 through a first contact connection via 180. The first front connection contact 170_2 is not in contact with the first contact connection via 180 and thus is not connected to the first contact connection via 180.

The second source/drain contact 270 may extend in the third direction Z on the first surface 100US of the substrate. The second source/drain contact 270 may be disposed on the second source/drain pattern 250. The second source/drain contact 270 is electrically connected to the second source/drain pattern 250.

The second source/drain contact 270 may include a second rear connection contact 270_1 and a second front connection contact 270_2. The second rear connection contact 270_1 may be connected to the second buried conductive pattern 80 through the second contact connection via 280. The second front connection contact 270_2 is not in contact with the second contact connection via 280 and thus is not connected to the second contact connection via 280.

The third source/drain contact 370 may extend in the third direction Z on the first surface 100US of the substrate. The third source/drain contact 370 may be disposed on the third source/drain pattern 350. The third source/drain contact 370 is electrically connected to the third source/drain pattern 350. The fourth source/drain contact 470 may extend in the third direction Z on the first surface 100US of the substrate. The fourth source/drain contact 470 may be disposed on the fourth source/drain pattern 450. The fourth source/drain contact 470 is electrically connected to the fourth source/drain pattern 450. Although not shown, the third and fourth source/drain contacts 370 and 470 may include a rear connection contact and a front connection contact.

For example, in FIG. 23, the first rear connection contact 170_1 and the second rear connection contact 270_1 may be disposed in the second direction Y. For example, the first rear connection contact 170_1 may be directly adjacent to the second rear connection contact 270_1 in the second direction Y. In FIG. 24, the first front connection contact 170_2 may be directly adjacent to the second front connection contact 270_2 in the second direction Y.

A height of an upper surface of the first source/drain contact 170 may be the same as that of an upper surface of the second source/drain contact 270 based on the upper surface of the field insulating layer 105. The height of the upper surface of the first source/drain contact 170 may be the same as a height of an upper surface of the third source/drain contact 370 and a height of an upper surface of the fourth source/drain contact 470 based on the upper surface of the field insulating layer 105.

The following description may be described using the first source/drain contact 170 and the second source/drain contact 270. The description of the first source/drain contact 170 and the second source/drain contact 270 may be applied to the third source/drain contact 370 and the fourth source/drain contact 470.

A first contact silicide layer 155 may be disposed between the first source/drain contact 170 and the first source/drain pattern 150. A second contact silicide layer 255 may be disposed between the second source/drain contact 270 and the second source/drain pattern 250. A third contact silicide layer 355 may be disposed between the third source/drain contact 370 and the third source/drain pattern 350. A fourth contact silicide layer 455 may be disposed between the fourth source/drain contact 470 and the fourth source/drain pattern 450.

A gate contact 175 may be disposed on the gate electrode 120. The gate contact 175 may be connected to the gate electrode 120. The gate contact 175 may connect the front wiring via 206 with the gate contact 175. The gate contact 175 may pass through the gate capping layer 145.

The front wiring via 206 may be disposed on the gate contact 175 and the source/drain contacts 170, 270, 370 and 470. The front wiring via 206 may be directly connected to the gate contact 175 and the source/drain contacts 170, 270, 370 and 470.

The front wiring via 206 may be disposed between the source/drain contacts 170, 270, 370 and 470 and the front wiring line 207. The front wiring via 206 may be disposed between the gate contact 175 and the front wiring line 207. The front wiring via 206 may connect the source/drain contacts 170, 270, 370 and 470 with the front wiring line 207. The front wiring via 206 may connect the gate contact 175 with the front wiring line 207.

The first front connection contact 170_2 and the second front connection contact 270_2 may be connected to the front wiring line 207 through the front wiring via 206. In the semiconductor device according to some embodiments, the first rear connection contact 170_1 and the second rear connection contact 270_1 may not be connected to the front wiring line 207. The front wiring via 206 may not be disposed on the first rear connection contact 170_1 and the second rear connection contact 270_1.

In FIG. 21, a height from the upper surface of the first active pattern AP1 to the upper surface of the first source/drain contact 170 may be the same as a height from the upper surface of the first active pattern AP1 to an upper surface 145US of the gate capping pattern, but the present disclosure is not limited thereto. The upper surface of the first source/drain contact 170 may be positioned at a boundary between the front wiring via 206 and the first source/drain contact 170.

Also, the height of the upper surface of the first source/drain contact 170 in FIG. 21 may be the same as the height of the upper surface of the first source/drain contact 170 in FIGS. 23 and 24, based on the second surface 100BS of the substrate, but is not limited thereto.

In the semiconductor device according to some embodiments, the source/drain contacts 170, 270, 370 and 470 and the front wiring via 206 may have a single-layered structure. For example, the source/drain contacts 170, 270, 370 and 470 and the front wiring via 206 may be formed of one conductive material. The source/drain contacts 170, 270, 370 and 470 and the front wiring via 206 may have a single conductive layer structure. In this case, the source/drain contacts 170, 270, 370 and 470 and the front wiring via 206 may include impurities that are unintentionally introduced in the process of forming the source/drain contacts 170, 270, 370 and 470 and the front wiring via 206. In addition, the gate contact 175 may have a single-layered structure.

The source/drain contacts 170, 270, 370 and 470, the front wiring via 206 and the gate contact 175 may include at least one of, for example, a metal or a metal alloy. The source/drain contacts 170, 270, 370 and 470, the front wiring via 206 and the gate contact 175 may include at least one of, for example, tungsten (W), molybdenum (Mo), ruthenium (Ru) or ruthenium-aluminum (RuAl), but the technical spirits of the present disclosure are not limited thereto.

The contact silicide layers 155, 255, 355 and 455 may include a metal silicide material.

The first buried conductive pattern 70 may be disposed between the first active pattern AP1 and the third active pattern AP3. The first buried conductive pattern 70 may overlap the field insulating layer 105 disposed between the first lower pattern BP1 and the third lower pattern BP3 in the third direction Z.

The second buried conductive pattern 80 may be disposed between the second active pattern AP2 and the fourth active pattern AP4. The second buried conductive pattern 80 may overlap the field insulating layer 105, which is disposed between the second lower pattern BP2 and the fourth lower pattern BP4, in the third direction Z.

Each of the first buried conductive pattern 70 and the second buried conductive pattern 80 may extend in the first direction X. In view of a plan view, at least a portion of the gate electrode 120 may cross the first buried conductive pattern 70 and the second buried conductive pattern 80. In the semiconductor device according to some embodiments, each of the first buried conductive pattern 70 and the second buried conductive pattern 80 may be formed in a line shape.

The first buried conductive pattern 70 and the second buried conductive pattern 80 may correspond to the second semiconductor element (135 of FIG. 15) described with reference to FIGS. 1 to 19. For example, the first buried conductive pattern 70 and the second buried conductive pattern 80 may be formed using the mask layer formed on the second surface 100BS of the substrate 100 in a state that the passivation layer (30 of FIG. 12) covering sides of the substrate 100 is formed.

The first buried conductive pattern 70 may be connected to the first rear connection contact 170_1 through the first contact connection via 180. The first buried conductive pattern 70 may be connected to the first rear wiring line 50.

The second buried conductive pattern 80 may be connected to the second rear connection contact 270_1 through the second contact connection via 280. Although not shown, the second buried conductive pattern 80 may be connected to the second rear wiring line 60.

The first buried conductive pattern 70 and the second buried conductive pattern 80 may pass through the substrate 100. The first buried conductive pattern 70 and the second buried conductive pattern 80 may extend from the second surface 100BS of the substrate to the first surface 100US of the substrate. For example, the first buried conductive pattern 70 and the second buried conductive pattern 80 may not be more protruded in the third direction Z than the first surface 100US of the substrate. Unlike the shown example, as another example, a portion of the first buried conductive pattern 70 and a portion of the second buried conductive pattern 80 may protrude more in the third direction Z than the first surface 100US of the substrate, and may be disposed in the field insulating layer 105.

A first buried insulating liner 71 may extend along sidewalls of the first buried conductive pattern 70. The first buried insulating liner 71 may be disposed between the first buried conductive pattern 70 and the substrate 100. A second buried insulating liner 81 may extend along sidewalls of the second buried conductive pattern 80. The second buried insulating liner 81 may be disposed between the second buried conductive pattern 80 and the substrate 100. Unlike the shown example, the buried insulating liners 71 and 81 may not be formed between the buried conductive patterns 70 and 80 and the substrate 100.

The first buried conductive pattern 70 may include a first buried conductive barrier layer 70a and a first buried conductive plug 70b. The second buried conductive pattern 80 may include a second buried conductive barrier layer 80a and a second buried conductive plug 80b.

The first buried conductive barrier layer 70a and the second buried conductive barrier layer 80a may include at least one of, for example, a metal, a conductive metal nitride, a conductive metal carbide, a conductive metal oxide, a conductive metal carbonitride, or a two-dimensional material. The first buried conductive plug 70b and the second buried conductive plug 80b may include at least one of a metal or a metal alloy. The first buried insulating liner 71 and the second buried insulating liner 81 may include an insulating material. Unlike the shown example, the first buried conductive pattern 70 and the second buried conductive pattern 80 may have a single conductive layer structure.

The two-dimensional (2D) material may include a two-dimensional allotrope or a two-dimensional compound, and may include at least one of, for example, graphene, boron nitride (BN), molybdenum sulfide, molybdenum selenide, tungsten sulfide, tungsten selenide or tantalum sulfide, but is not limited thereto. That is, since the two-dimensional materials described above are only examples, the two-dimensional material that may be included in the semiconductor device of the present disclosure is not limited by the above-described materials.

The first contact connection via 180 may be disposed between the first source/drain contact 170 and the first buried conductive pattern 70. For example, the first contact connection via 180 connects the first rear connection contact 170_1 with the first buried conductive pattern 70. The first contact connection via 180 may be directly connected to the first rear connection contact 170_1. For example, the first contact connection via 180 may be connected to the first buried conductive pattern 70 by passing through the source/drain etch stop layer 185 and the field insulating layer 105.

The first contact connection via 180 may be disposed between the first source/drain contact 170 and the first buried conductive pattern 70. For example, the first contact connection via 180 connects the first rear connection contact 170_1 with the first buried conductive pattern 70. The first contact connection via 180 may be directly connected to the first rear connection contact 170_1. For example, the first contact connection via 180 may be connected to the first buried conductive pattern 70 by passing through the source/drain etch stop layer 185 and the field insulating layer 105.

The second contact connection via 280 may be disposed between the second source/drain contact 270 and the second buried conductive pattern 80. For example, the second contact connection via 280 connects the second rear connection contact 270_1 with the second buried conductive pattern 80. The second contact connection via 280 may be directly connected to the second rear connection contact 270_1. For example, the second contact connection via 280 may be connected to the second buried conductive pattern 80 by passing through the source/drain etch stop layer 185 and the field insulating layer 105.

A width of the first contact connection via 180 in the second direction Y may be increased as it becomes farther away from the second surface 100BS of the substrate. A width of the second contact connection via 380 in the second direction Y may be increased as it becomes farther away from the second surface 100BS of the substrate.

The first contact connection via 180 and the second contact connection via 280 may have a multi-layered structure. That is, the first contact connection via 180 and the second contact connection via 280 may have a multi-conductive layer structure. The first contact connection via 180 may include a first contact connection barrier layer 180a and a first contact connection plug 180b. The second contact connection via 280 may include a second contact connection barrier layer 280a and a second contact connection plug 280b.

The first contact connection barrier layer 180a is extended along sidewalls of the first contact connection plug 180b. The second contact connection barrier layer 280a is extended along sidewalls of the second contact connection plug 280b.

The first contact connection plug 180b may be directly connected to the first rear connection contact 170_1. The first contact connection plug 180b may include an upper surface facing the first rear connection contact 170_1. The upper surface of the first contact connection plug 180b is in contact with the first rear connection contact 170_1. The second contact connection plug 280b may be directly connected to the second rear connection contact 270_1. The second contact connection plug 280b may include an upper surface facing the second rear connection contact 270_1. An upper surface of the second contact connection plug 280b is in contact with the second rear connection contact 270_1.

The first contact connection barrier layer 180a and the second contact connection barrier layer 280a may include at least one of, for example, a metal, a conductive metal nitride, a conductive metal carbide, a conductive metal oxide, a conductive metal carbonitride, or a two-dimensional material. The first contact connection plug 180b and the second contact connection plug 280b may include at least one of a metal or a metal alloy.

For example, the first contact connection plug 180b may include the same material as that of the first rear connection contact 170_1. The second contact connection plug 280b may include the same material as that of the second rear connection contact 270_1. In this case, a boundary between the contact connection plugs 180b and 280b and the rear connection contacts 170_1 and 270_1 may not be distinguished.

For another example, the first contact connection plug 180b may include a material different from that of the first rear connection contact 170_1. The second contact connection plug 280b may include a material different from that of the second rear connection contact 270_1.

Unlike the shown example, the first contact connection via 180 and the second contact connection via 280 may have a single conductive layer structure.

The first rear wiring line 50 and the second rear wiring line 60 may correspond to the second semiconductor element (135 of FIG. 15) described with reference to FIGS. 1 to 19. For example, the first rear wiring line 50 and the second rear wiring line 60 may be formed using the mask layer formed on the second surface 100BS of the substrate 100 in a state that the passivation layer (30 of FIG. 12) covering the sides of the substrate 100 is formed.

The first rear wiring line 50 and the second rear wiring line 60 may be disposed on the second surface 100BS of the substrate. For example, the first rear wiring line 50 and the second rear wiring line 60 may extend in the second direction Y, respectively, but are not limited

The first rear wiring line 50 may be connected to the first buried conductive pattern 70. The first rear wiring line 50 may be connected to the first rear connection contact 170_1 through the first buried conductive pattern 70. The first rear connection contact 170_1 connects the first rear wiring line 50 with the first source/drain pattern 150. The first front connection contact 170_2 is not connected to the first rear wiring line 50.

Although not shown, the second rear wiring line 60 may be connected to the second buried conductive pattern 80. The second rear wiring line 60 may be connected to the second rear connection contact 270_1 through the second buried conductive pattern 80. The second rear connection contact 270_1 connects the second rear wiring line 60 with the second source/drain pattern 250. The second front connection contact 270_2 is not connected to the second rear wiring line 60.

For example, the first rear wiring line 50 and the second rear wiring line 60 may be power lines for supplying a power source to the semiconductor device. For another example, the first rear wiring line 50 and the second rear wiring line 60 may be signal lines for supplying an operation signal of the semiconductor device. For another example, one of the first rear wiring line 50 and the second rear wiring line 60 may be a power line, and the other one thereof may be a signal line.

The first rear wiring via 55 may be disposed between the first rear wiring line 50 and the first buried conductive pattern 70. The first rear wiring via 55 connects the first rear wiring line 50 with the first buried conductive pattern 70. Although not shown, the second rear wiring via may be disposed between the second rear wiring line 60 and the second buried conductive pattern 80. The second rear wiring via connects the second rear wiring line 60 with the second buried conductive pattern 80.

The first rear wiring line 50 and the second rear wiring line 60 are shown as having a single conductive layer structure, but the present disclosure is not limited thereto. Unlike the shown example, the first rear wiring line 50 and the second rear wiring line 60 may have a multi-conductive layer structure that includes a rear wiring barrier layer and a rear wiring plug layer, like the front wiring line 207. The first rear wiring via 55 is shown as having a single conductive layer structure, but is not limited thereto.

The first rear wiring line 50, the second rear wiring line 60 and the first rear wiring via 55 may include at least one of, for example, a metal, a metal alloy, a conductive metal nitride, a conductive metal carbide, a conductive metal oxide, a conductive metal carbonitride, or a two-dimensional material. The boundary between the first rear wiring line 50 and the first rear wiring via 55 is shown as being distinguished, but is not limited thereto. The first rear wiring line 50 and the first rear wiring via 55 may have an integral structure having no distinction of a boundary surface.

A lower interlayer insulating layer 290 may be disposed on the second surface 100BS of the substrate. The first rear wiring line 50, the first rear wiring via 55 and the second rear wiring line 60 may be disposed in the lower interlayer insulating layer 290. The lower interlayer insulating layer 290 may include at least one of, for example, silicon oxide, silicon nitride, silicon carbonitride, silicon oxynitride, or a low-k material.

A first etching stop layer 196 and a second upper interlayer insulating layer 191 may be disposed on the first upper interlayer insulating layer 190. The second upper interlayer insulating layer 191 may cover sidewalls of the front wiring via 206.

A second etch stop layer 197 and a third upper interlayer insulating layer 192 may be sequentially disposed on the second upper interlayer insulating layer 191. The second etch stop layer 197 may be disposed between the second upper interlayer insulating layer 191 and the third upper interlayer insulating layer 192.

The first etch stop layer 196 and the second etch stop layer 197 may include at least one of, for example, silicon nitride (SiN), silicon oxynitride (SiON), silicon oxycarbonitride (SiOCN), silicon boron nitride (SiBN), silicon boron oxynitride (SiOBN), silicon oxycarbide (SiOC), aluminum oxide (AlO), aluminum nitride (AlN), aluminum oxycarbide (AlOC) or their combination. The third upper interlayer insulating layer 192 may include at least one of, for example, silicon oxide, silicon nitride, silicon carbonitride, silicon oxynitride, or a low-k material.

The front wiring line 207 may be disposed in the third upper interlayer insulating layer 192. The front wiring line 207 is disposed on the first surface 100US of the substrate.

The front wiring line 207 may be connected to the source/drain contacts 170, 270, 370 and 470 and the gate contact 175. The front wiring line 207 may be connected to the source/drain contacts 170, 270, 370 and 470 through the front wiring via 206. The front wiring line 207 may be connected to the gate contact 175 through the front wiring via 206.

The front wiring line 207 may include a front wiring barrier layer 207a and a front wiring plug 207b. The front wiring barrier layer 207a may include at least one of, for example, a metal, a conductive metal nitride, a conductive metal carbide, a conductive metal oxide, a conductive metal carbonitride, or a two-dimensional material. The front wiring plug 207b may include at least one of, for example, a metal or a metal alloy. The front wiring line 207 is shown as having a multi-conductive layer structure, but is not limited thereto. Unlike the shown example, the front wiring line 207 may have a single conductive layer structure like the rear wiring lines 50 and 60.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

In concluding the detailed description, those skilled in the art will appreciate that many variations and modifications may be made to the presented embodiments without substantially departing from the principles an aspects of inventive concepts. Therefore, the disclosed presented embodiments of are used in a generic and descriptive sense only and not for purposes of limitation.

What is claimed is:

1. A method for fabricating a semiconductor device, the method comprising:
forming a first substrate including a first surface and a second surface, which are opposite each other;
forming a first semiconductor element on the first surface;
adhering the first substrate onto a second substrate so that an upper surface of the second substrate faces the first surface of the first substrate;
removing an edge region of the first substrate;
forming a passivation layer surrounding first sides of the first substrate; and
forming a second semiconductor element on the second surface of the first substrate,
wherein the passivation layer is not formed on the second surface of the first substrate.

2. The method of claim 1, wherein
the adhering the first substrate onto the second substrate includes forming a first recess on the first surface of the first substrate, and
the adhering the first substrate onto the second substrate including arranging the first substrate so that the first recess faces the upper surface of the second substrate, and
the removing the edge region of the first substrate includes removing a portion of the first substrate on the second surface of the first substrate to expose the first recess, and removing the edge region outside the first recess.

3. The method of claim 2, wherein the adhering the first substrate onto the second substrate further includes:
forming a second recess on the upper surface of the second substrate, the second recess corresponding to the first recess; and
aligning the first substrate on the second substrate by using the first recess and the second recess.

4. The method of claim 1, wherein the passivation layer includes a photoresist material.

5. The method of claim 1, wherein the passivation layer surrounds second sides of the second substrate.

6. The method of claim 1, wherein the passivation layer is not formed on second sides of the second substrate.

7. The method of claim 1, wherein a first width between the first sides of the first substrate is smaller than a second width between second sides of the second substrate.

8. The method of claim 1, wherein the second semiconductor element includes a power supply wiring line.

9. The method of claim 1, wherein the adhering the first substrate onto the second substrate includes:
forming an adhesive layer on the first surface; and
adhering the adhesive layer to the upper surface of the second substrate.

10. The method of claim 1, further comprising:
removing the passivation layer.

11. The method of claim 1, wherein
the forming the second semiconductor element includes forming a mask layer on the second surface and patterning the mask layer by removing a portion of the mask layer, and
the passivation layer and the mask layer include different materials.

12. A method for fabricating a semiconductor device, the method comprising:
adhering a second substrate on a first substrate, the second substrate including a second surface facing a first surface of the first substrate;
forming a passivation layer surrounding sides of the second substrate on the first substrate;
forming a first semiconductor element on a third surface of the second substrate, the third surface of the first substrate being opposite the second surface of the second substrate; and
removing the passivation layer, wherein
the first substrate has a first width,
the second substrate has a second width,
the second width is smaller than the first width, and
the passivation layer is not formed on the third surface of the second substrate.

13. The method of claim 12, wherein
the first width is between outermost sides of the first substrate, and
a third width between outermost points of the passivation layer is greater than the first width between outermost sides of the first substrate.

14. The method of claim 12, wherein
a height of an uppermost surface of the passivation layer is greater than a height of the third surface of the second substrate based on the first surface of the first substrate.

15. The method of claim 12, wherein the forming the passivation layer includes:
forming a pre-passivation layer covering the third surface of the second substrate and the sides of the second substrate, and
removing a portion of the pre-passivation layer on the third surface of the second substrate.

16. The method of claim 12, wherein
sides of the first substrate are curved, and
the sides of the second substrate are flat.

17. The method of claim 16, wherein the first semiconductor element and the passivation layer do not overlap each other.

18. The method of claim 12, further comprising:
separating the second substrate from the first substrate.

19. The method of claim 12, further comprising:
forming a second semiconductor element on the second surface of the second substrate before the adhering the second substrate on the first substrate, wherein
the first semiconductor element and the second semiconductor element are electrically connected each other.

20. A method for fabricating a semiconductor device, the method comprising:
forming a first substrate including a first surface and a second surface, which are opposite each other;
forming a first semiconductor element on the first surface;
adhering the first substrate onto an upper surface of a second substrate so that the upper surface of the second substrate faces the first surface;
forming first sides of the first substrate by removing an edge region of the first substrate;
forming a mask layer on the second surface of the first substrate;
forming a passivation layer surrounding the first sides of the first substrate and sides of the mask layer;
patterning the mask layer to provide a patterned mask layer;
removing the passivation layer; and
forming a second semiconductor element electrically connected to the first semiconductor element on the second surface of the first substrate, the forming the second semiconductor element including using the patterned mask layer as a patterning mask, wherein
a first width between the first sides of the first substrate is smaller than a second width between second sides of the second substrate,
the passivation layer is not formed on the second surface of the first substrate, and
the passivation layer includes a photoresist material.
